(19) United States
(12) Patent Application Publication
(10) Pub. No.: US 2023/0045843 A1
(43) Pub. Date: Feb. 16, 2023

(54) POWER DEVICE AND MANUFACTURING METHOD THEREOF

(71) Applicant: Richtek Technology Corporation, Zhubei City (TW)

(72) Inventors: Yu-Ting Yeh, Miaoli (TW); Kuo-Hsuan Lo, Taoyuan (TW); Chien-Hao Huang, Penghu (TW); Chu-Feng Chen, Hsinchu (TW); Wu-Te Weng, Hsinchu (TW)

(21) Appl. No.: 17/749,071

(22) Filed: May 19, 2022

(30) Foreign Application Priority Data
Aug. 16, 2021 (TW) 110130069

(51) Int. Cl. H01L 29/78; H01L 29/06; H01L 29/10; H01L 29/40; H01L 21/265; H01L 21/266; H01L 21/3105; H01L 21/765; H01L 29/66

(52) U.S. Cl. CPC H01L 29/7816; H01L 29/0653; H01L 29/1095; H01L 29/402; H01L 21/26513; H01L 21/266; H01L 21/31053; H01L 21/765; H01L 29/66681

(57) ABSTRACT

A power device includes: a semiconductor layer, a well region, a body region, a gate, a source, a drain, a field oxide region, and a self-aligned drift region. The field oxide region is formed on an upper surface of the semiconductor layer, wherein the field oxide region is located between the gate and the drain. The field oxide region is formed by steps including a chemical mechanical polish (CMP) process step. The self-aligned drift region is formed in the semiconductor layer, wherein the self-aligned drift region is entirely located vertically below and in contact with the field oxide region.

### CROSS REFERENCE

The present invention claims priority to TW 110130069 filed on Aug. 16, 2021.

### BACKGROUND OF THE INVENTION

### Field of Invention

The present invention relates to a power device and a manufacturing method of the power device; particularly, it relates to such power device having a field oxide region and a self-aligned drift region, and a manufacturing method thereof.

### Description of Related Art

Please refer to FIG. 1A and FIG. 1B. FIG. 1A shows a schematic diagram in top view of a conventional power device 100, whereas, FIG. 1B shows a schematic diagram in cross-section view of a conventional power device 100. FIG. 1B shows a schematic diagram in cross-section view of a power device taken along A-A′ line of FIG. 1A. The term “power device”, in the context of this invention, refers to a semiconductor device operating to transmit power, whose drain, when implemented by a metal-oxide-semiconductor field effect transistor (MOSFET), is typically required to receive a voltage which is higher than 5V during normal operation. Generally, a drift region 12a (as indicated by a dashed frame in FIG. 1B) is located between a drain and a gate of the power device 100. The drift region 12a serves to separate the drain 19 from a body region 16. A lateral length of the drift region 12a is determined according to an operation voltage that the power device is required to withstand in normal operation. As shown in FIG. 1A and FIG. 1B, the power device 100 comprises: a well 12, an isolation structure 13, a body region 16, the gate 17, a source 18 and the drain 19. The well 12 has N conductivity type and is formed on a substrate 11. The isolation structure 33 is a local oxidation of silicon (LOCOS) structure as shown in FIG. 1B, for defining an operation region 13a, which is an active region for the operation of the power device 100. The range of the operation region 13a is as indicated by a thick dashed frame in FIG. 1A. The prior art shown in FIG. 1A and FIG. 1B has the following drawbacks. In order to enhance the breakdown voltage of the power device 100, the length of the drift region 12a in the channel direction can be prolonged. However, a longer length of the drift region 12a will undesirably increase the conduction resistance of the power device 100 and decrease its operation speed. Besides, there is a large difference between the concentration of N type impurities of the drift region 12a and the concentration of N type impurities of the drain 19, and there is a large voltage difference between a voltage coupled to the drift region 12a and a voltage coupled to the drain 19, which may be in an order of 5V to several hundred volts, such that the breakdown voltage of the power device 100 is undesirably limited. Consequently and undesirably, an application scope of the power device 100 is limited, and the performance of the power device 100 is not satisfactory.

In view of the above, to overcome the drawbacks in the prior art, the present invention proposes a power device and a manufacturing method thereof, which are capable of enhancing an OFF breakdown voltage of the power device when the power device is in OFF operation, so as to enhance the withstand voltage and reduce the conduction resistance of the power device.

### SUMMARY OF THE INVENTION

From one perspective, the present invention provides a power device, comprising: a semiconductor layer, which is formed on a substrate, and has a top surface; a well having a first conductivity type, which is formed in the semiconductor layer, wherein the well is located below and in contact with the top surface; a body region having a second conductivity type, which is formed in the semiconductor layer, wherein the body region is located below and in contact with the top surface, and wherein the body region is in contact with the well in a channel direction; a gate, which is formed on the top surface, wherein a part of the body region is located vertically below and in contact with the gate, to serve as an inversion current channel in an ON operation of the power device, and wherein a part of the well is located vertically below the gate, to serve as a drift current channel in the ON operation of the power device; a source and a drain having the first conductivity type, which are formed below and in contact with the top surface, wherein the source and the drain are located below and outside two sides of the gate respectively, wherein the side of the gate which is closer to the source is a source side and the side of the gate which is closer to the drain is a drain side, and wherein the source is located in the body region, and the drain is located in the well outside the drain side; a field oxide region, which is formed on the upper surface, wherein the field oxide region is located between the gate and the drain, and wherein the field oxide region is formed by steps including a chemical mechanical polish (CMP) process step; and a self-aligned drift region having the first conductivity type, which is formed in the semiconductor layer, wherein the self-aligned drift region is entirely located vertically below and in contact with the field oxide region.

From another perspective, the present invention provides a manufacturing method of the power device, comprising: forming a semiconductor layer on a substrate, wherein the semiconductor layer has a top surface; forming a well in the semiconductor layer, wherein the well has a first conductivity type, wherein the well is located below and in contact with the top surface; forming a body region in the semiconductor layer, wherein the body region has a second conductivity type, wherein the body region is located below and in contact with the top surface, and wherein the body region is in contact with the well in a channel direction; forming a gate on the top surface, wherein a part of the body region is located vertically below and in contact with the gate, to serve as an inversion current channel in an ON operation of the power device, and wherein a part of the well is located vertically below the gate, to serve as a drift current channel in the ON operation of the power device; forming a source and a drain below and in contact with the top surface, wherein each of the source and the drain has the first conductivity type, wherein the source and the drain are located below and outside two sides of the gate respectively, wherein the side of the gate which is closer to the source is a source side and the side of the gate which is closer to the drain is a drain side, and wherein the source is located in the body region, and the drain is located in the well outside the drain side; forming a field oxide region on the upper surface by steps including a chemical mechanical polish (CMP) process step, wherein the field oxide region is located between the gate and the drain; and forming a self-aligned drift region in the semiconductor layer, wherein the self-aligned drift region has the first conductivity type, and wherein the self-aligned drift region is entirely located vertically below and in contact with the field oxide region.

In one embodiment, the power device further comprises: a field plate which is conductive and which is formed on and in contact with the field oxide region, wherein the field plate is electrically connected to a predetermined voltage level, so as to relieve an electric field distribution when the power device is in operation.

In one embodiment, a concentration of the first conductivity type impurities of the self-aligned drift region is lower than a concentration of the first conductivity type impurities of the drain, and the concentration of the first conductivity type impurities of the self-aligned drift region is higher than a concentration of the first conductivity type impurities of the well.

In one embodiment, the self-aligned drift region and the field oxide region are defined via a same lithography process step.

In one embodiment, the field plate is electrically connected to the source.

In one embodiment, the manufacturing method of the power device further comprises: forming a mask on and in contact with the upper surface via a lithography process step, wherein the mask serves to define the field oxide region and the self-aligned drift region; implanting first conductivity type impurities in the region defined by the mask in the form of accelerated ions by an ion implantation process step, to form the self-aligned drift region; depositing an oxide layer via a deposition process step, and removing part of the oxide layer which does not belong to the region defined by the mask via the CMP process step; and removing the mask.

Advantages of the present invention include: that by covering the entire low voltage region and exposing only the top surface of the high voltage region, the present invention can protect the low voltage region; that, the present invention can prevent the isolation structure from being etched by a mask; that the present invention can form the self-aligned drift region and the field oxide region by one single mask; that the present invention can eliminate an undesirable effect on the low voltage region caused by a heating process step by replacing the heating process step with a CMP process step; and that the present invention can form the high voltage region which has an increasing impurities concentration distribution of the first conductivity type by the self-aligned drift region.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a schematic diagram in top view of a conventional power device, whereas, FIG. 1B shows a schematic diagram in cross-section view of a conventional power device.

FIG. 2A shows a schematic diagram in top view of a power device according to an embodiment of the present invention, whereas,

FIG. 2B shows a schematic diagram in cross-section view of a power device according to an embodiment of the present invention.

FIG. 3A shows a schematic diagram in top view of a power device according to another embodiment of the present invention, whereas, FIG. 3B shows a schematic diagram in cross-section view of a power device according to another embodiment of the present invention.

FIG. 4A to FIG. 4L show schematic diagrams in cross-section view of a manufacturing method for a power device according to an embodiment of the present invention.

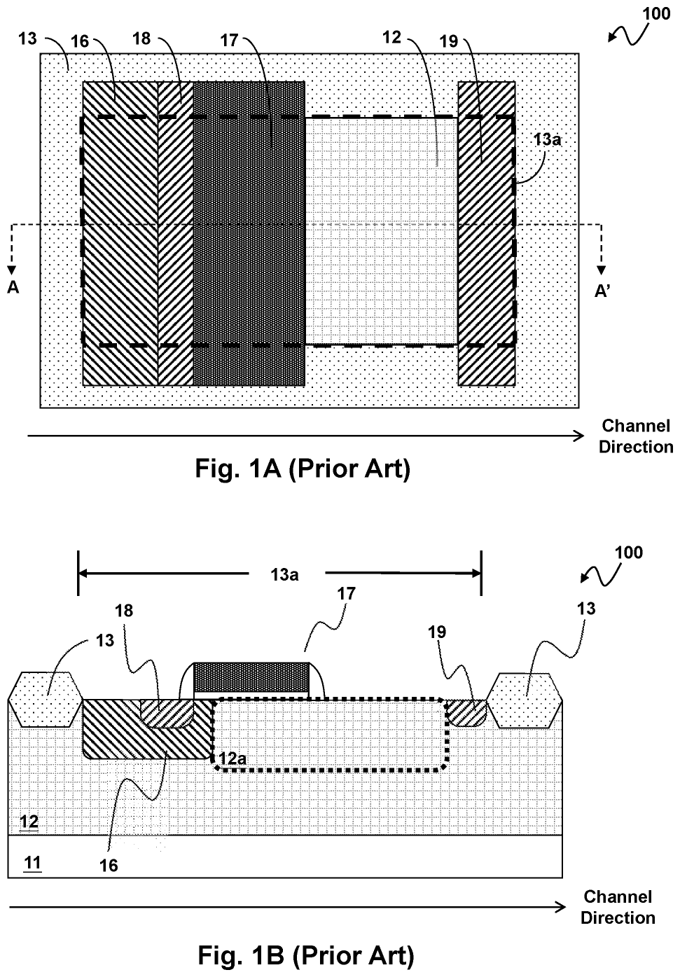

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

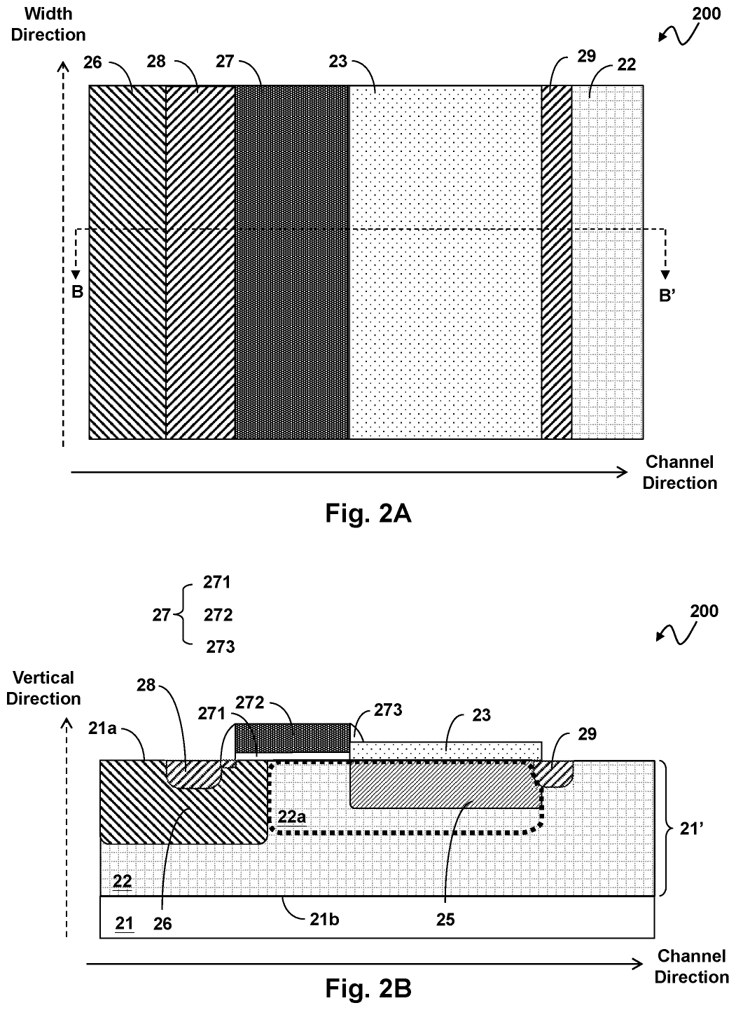

Please refer to FIG. 2A and FIG. 2B. FIG. 2A shows a schematic diagram in top view of a power device according to an embodiment of the present invention, whereas, FIG. 2B shows a schematic diagram in cross-section view of a power device according to an embodiment of the present invention. FIG. 2B shows a schematic diagram in cross-section view of a power device taken along B-B′ line of FIG. 2A. As shown in FIG. 2A and FIG. 2B, the power device 200 includes: a semiconductor layer 21′, a well 22, a field oxide region 23, a self-aligned drift region 25, a body region 26, a gate 27, a source 28 and a drain 29. The semiconductor layer 21′ is formed on the substrate 21. Each of the well 22, the self-aligned drift region 25, the source 28 and the drain 29 has a first conductivity type. The body region 26 has a second conductivity type. The power device 200 can be for example a laterally diffused metal oxide semiconductor (LDMOS) device, as shown in FIG. 2A and FIG. 2B. The power device according to the present invention can be applied in for example a power stage circuit in a switching power regulator circuit, which is well known to those skilled in the art, so the details thereof are not redundantly explained here.

The semiconductor layer 21′ is formed on the substrate 21, and the semiconductor layer 21′ has a top surface 21a and a bottom surface 21b that is opposite to the top surface 21a in the vertical direction (as indicated by the direction of the dashed arrow in FIG. 2B). The substrate 21 is, for example but not limited to, a P conductivity type or an N conductivity type silicon substrate. The semiconductor layer 21′, for example, is formed on the substrate 21 by an epitaxial growth process step, or, a part of the substrate 21 is used as the semiconductor layer 21′. The semiconductor layer 21′ can be formed by any method known to a person having ordinary skill in the art, so the details thereof are not redundantly explained here.

Still referring to FIG. 2A and FIG. 2B, the well 22 has a first conductivity type, and is formed in the semiconductor layer 21′. The well 22 is located below and in contact with the top surface 21a. The body region 26 has a second conductivity type, and is formed in the semiconductor layer 21′. The body region 26 is located below and in contact with the top surface 21a. The body region 26 is in contact with the well 22 in a channel direction (as indicated by the direction of the solid arrow in FIG. 2B). The gate 27 is formed on the top surface 21a. A part of the body region 26 is located vertically below and in contact with the gate 27, to serve as an inversion current channel in an ON operation of the power device 200. And, a part of the well 22 which is in contact with the body region 26 is located vertically below the gate 27, to serve as a drift current channel (as indicated by a thick dotted frame in FIG. 2B) in the ON operation of the power device 200. Each of the source 28 and the drain 29 has the first conductivity type, and is formed below and in contact with the top surface 21a. The source 28 and the drain 29 are located below and outside two sides of the gate 27 respectively. The side of the gate 27 which is closer to the source 28 is a source side and the side of the gate 27 which is closer to the drain 29 is a drain side, wherein the source 28 is located in the body region 26, and the drain 29 is located in the well 22 outside the drain side.

The field oxide region 23 is formed on the upper surface 21a, wherein the field oxide region 23 is located between the gate 27 and the drain 29. In one embodiment, the field oxide region 23 is formed by steps including a chemical mechanical polish (CMP) process step. The self-aligned drift region 25 has the first conductivity type and is formed in the semiconductor layer 21′. The self-aligned drift region 25 is entirely located vertically below and in contact with the field oxide region 23.

The self-aligned drift region 25 and the field oxide region 23 are defined via a same photomask by a same lithography process step. In one embodiment, the concentration of the first conductivity type impurities of the self-aligned drift region 25 is lower than the concentration of the first conductivity type impurities of the drain 29, and the concentration of the first conductivity type impurities of the self-aligned drift region 25 is higher than the concentration of the first conductivity type impurities of the well 22.

Note that the gate 27 includes a dielectric layer 271 in contact with the top surface 21a, a conductive layer 272 on the dielectric layer 271, and a spacer layer 273 which is electrically insulative. The gate 27 turns ON and turns OFF the power device 200 according to a control signal.

Still referring to FIG. 2B, a drift region 22a is formed in the well 22 between the drain 29 and the body region 26 in the channel direction, and is in contact with the top surface 21a, to separate the drain 29 from the body region 26 and to serve as a drift current channel in the ON operation of the power device 200.

Note that the term “inversion current channel” means thus. Taking this embodiment as an example, when the power device 200 operates in ON operation due to the voltage applied to the gate 27, an inversion layer is formed below the gate 27, so that a conduction current flows through the region of the inversion layer, which is the inverse current channel known to a person having ordinary skill in the art.

Note that the term “drift current channel” means thus. Taking this embodiment as an example, the drift current channel refers to a region where the conduction current passes through in a drifting manner when the power device 200 operates in ON operation, which is known to a person having ordinary skill in the art.

Note that the top surface 21a as referred to does not mean a completely flat plane but refers to the surface of the semiconductor layer 21′.

Note that the above-mentioned “first conductivity type” and “second conductivity type” mean that impurities of corresponding conductivity types are doped in regions of the power device (for example but not limited to the aforementioned well region, body region, source and drain, etc.), so that the regions have the corresponding conductivity types. For example the first conductivity type is N-type and the second conductivity type is P-type, or the first conductivity type is P-type and the second conductivity type is N-type. The first conductivity type has a conductivity type opposite to a conductivity type of the second conductivity type.

In addition, the term “power device” refers to a semiconductor device operating to transmit power, whose drain, when implemented by a metal-oxide-semiconductor field effect transistor (MOSFET), is typically required to receive a voltage which is higher than 5V during normal operation. A lateral distance (length of the drift region) between the body region 26 and the drain 29 of the power device 200 is determined according to the required operation voltage during normal operation, so that the device can operate at or higher than the aforementioned specific voltage, which is known to a person having ordinary skill in the art, so the details thereof are not redundantly explained here.

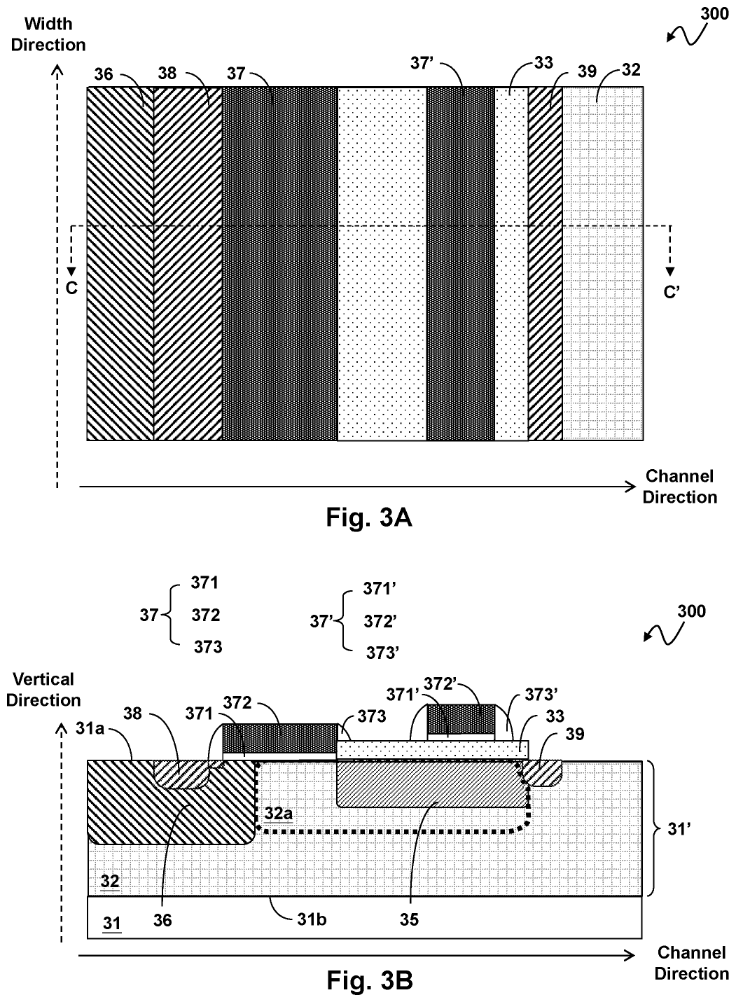

Please refer to FIG. 3A and FIG. 3B. FIG. 3A shows a schematic diagram in top view of a power device according to another embodiment of the present invention, whereas, FIG. 3B shows a schematic diagram in cross-section view of a power device according to another embodiment of the present invention. FIG. 3B shows a schematic diagram in cross-section view of a power device taken along C-C′ line of FIG. 3A. As shown in FIG. 3A and FIG. 3B, the power device 300 includes: a semiconductor layer 31′, a well 32, a field oxide region 33, a self-aligned drift region 35, a body region 36, a gate 37, a field plate 37′, a source 38 and a drain 39. Each of the well 32, the self-aligned drift region 35, the source 38 and the drain 39 has a first conductivity type. The body region 36 has a second conductivity type.

Please still refer to FIG. 3A and FIG. 3B. This embodiment of FIG. 3A and FIG. 3B is different from the embodiment of FIG. 2A and FIG. 2B, in that: the power device 300 of this embodiment includes a field plate 37′ which is conductive. The field plate 37′ is formed on and in contact with the field oxide region 33. The field plate 37′ is electrically connected to a predetermined voltage level, so as to relieve an electric field distribution when the power device 300 is in operation. In one embodiment, the field plate 37′ is electrically connected to the source 38. In one embodiment, the field plate 37′ can be formed by the same process step for forming the gate 37. In this embodiment, as shown in FIG. 3B, the field plate 37′ includes: a dielectric layer 371′ in contact with the top surface 31a, a conductive layer 372′ on the dielectric layer 371′ , and a spacer layer 373′ which is electrically insulative. In another embodiment, the field plate 37′ can be a metal silicide layer formed by a metal silicidation process step, or a metal layer formed by a metal formation process step (including deposition and patterning).

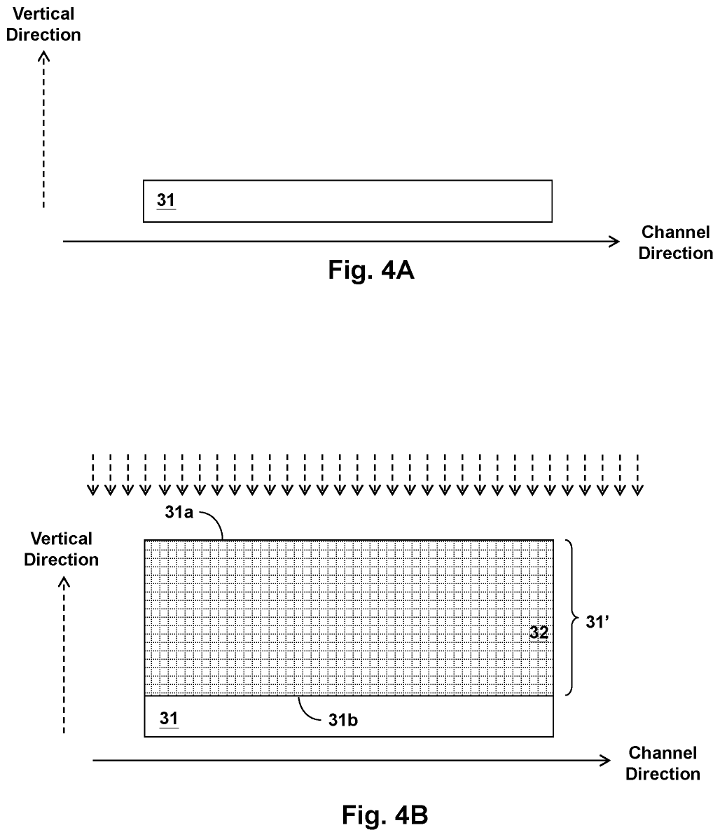

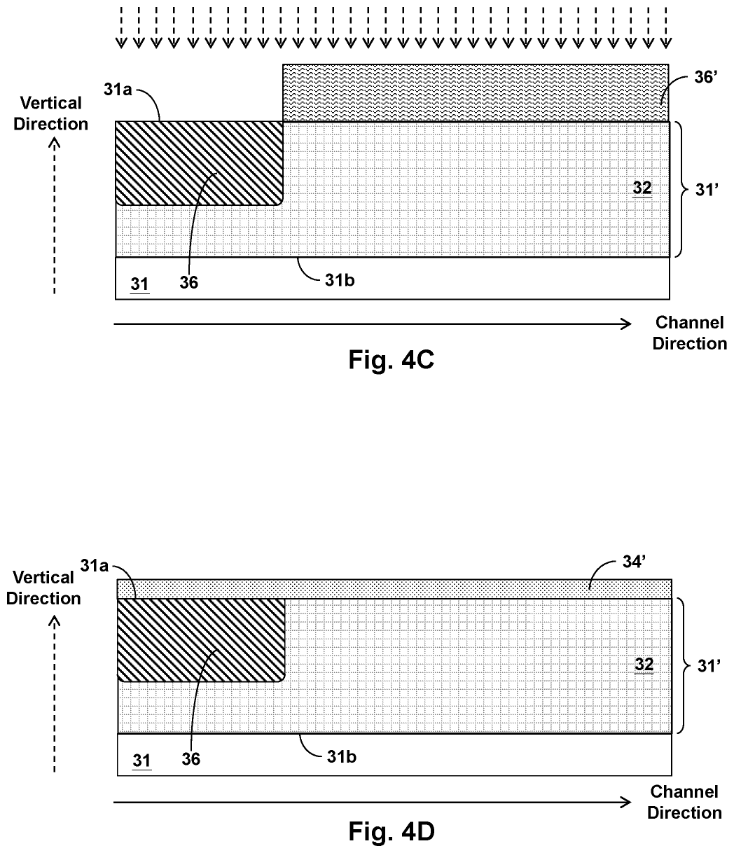

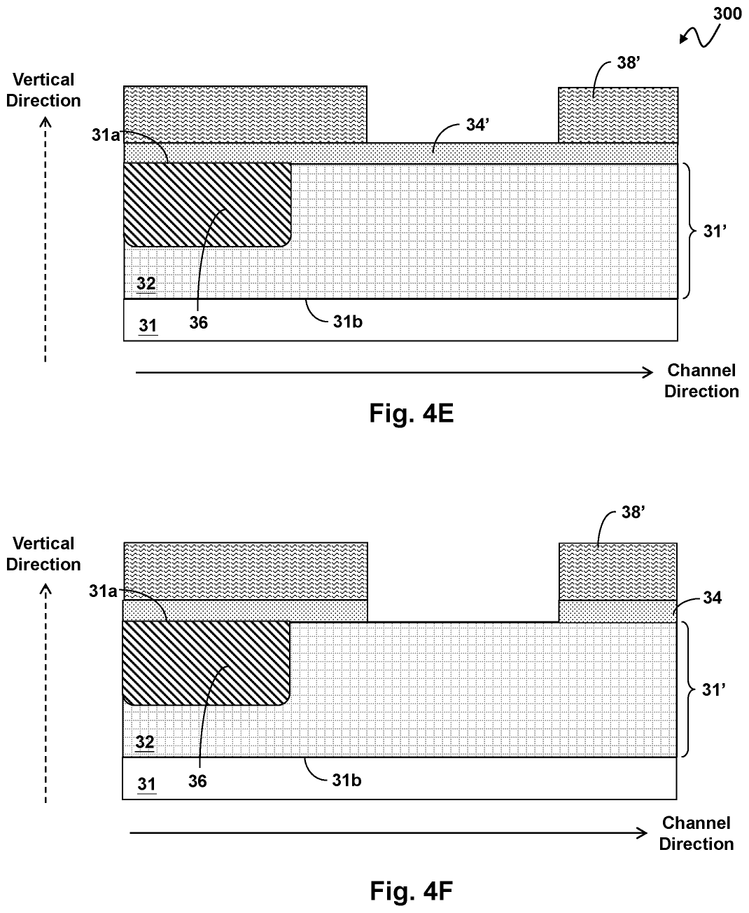

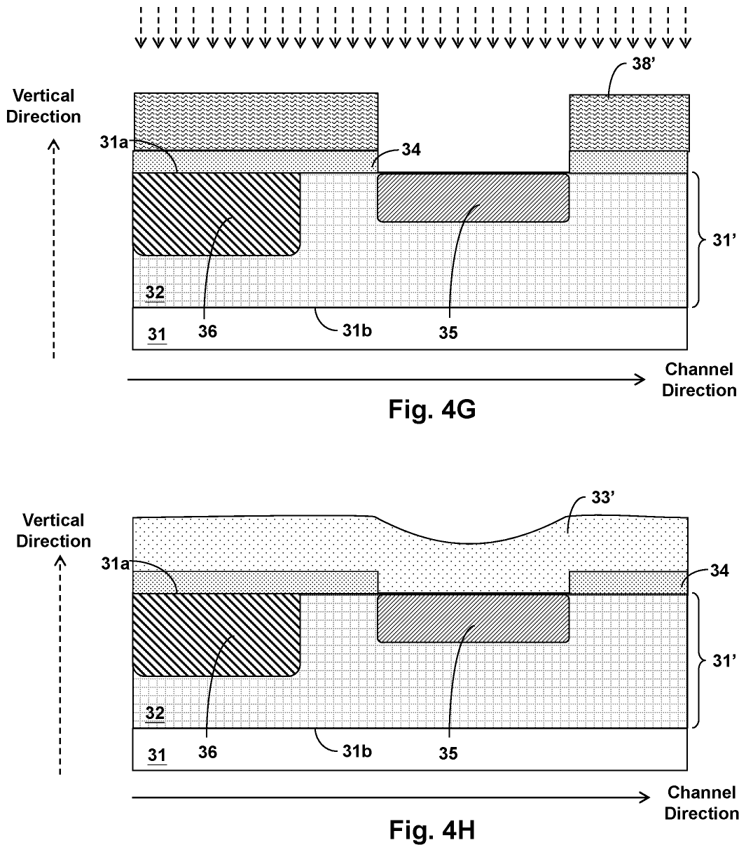

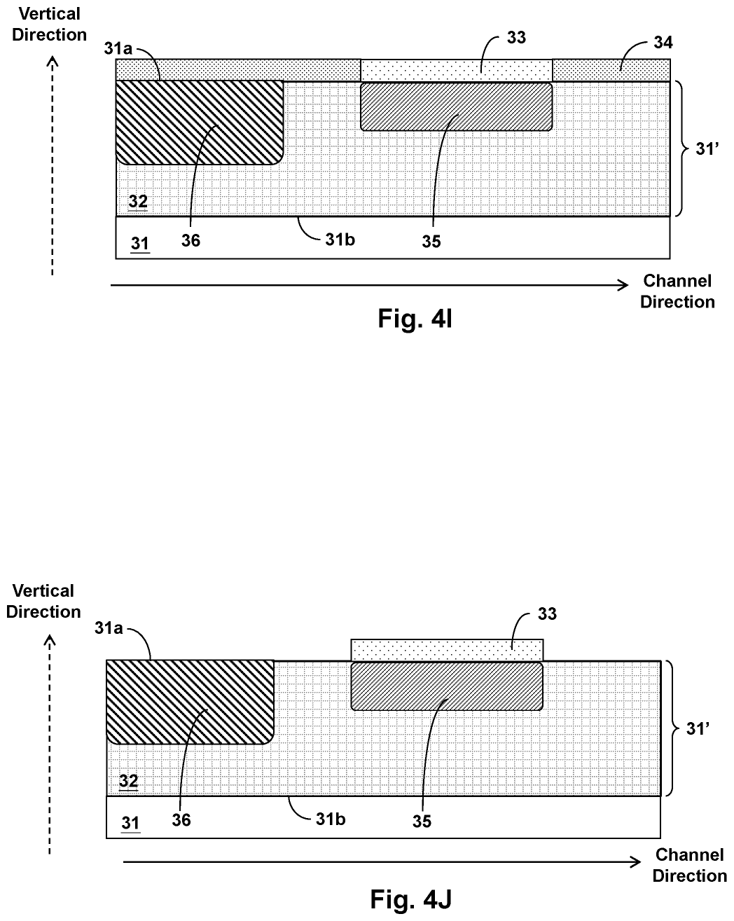

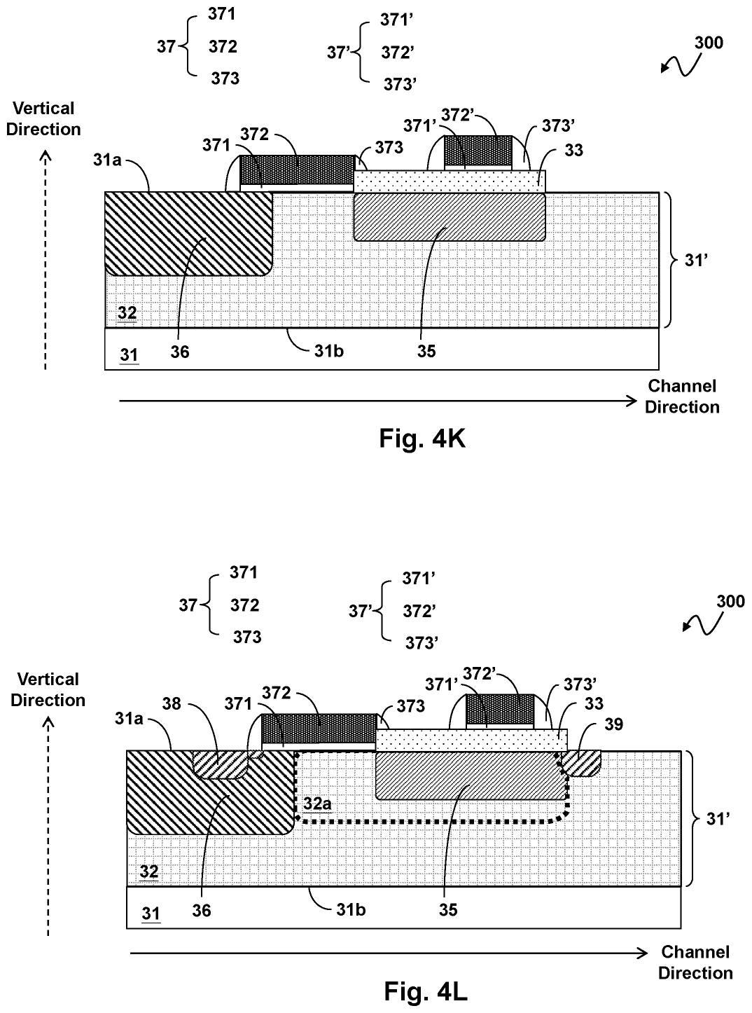

Please refer to FIG. 4A to FIG. 4L, which show schematic diagrams in cross-section view of a manufacturing method for a power device according to an embodiment of the present invention. As shown in FIG. 4A, first, a substrate 31 is provided. The substrate 31 is, for example but not limited to, a P conductivity type or an N conductivity type silicon substrate. Next, as shown in FIG. 4B, a semiconductor layer 31′ is formed on the substrate 31, and the semiconductor layer 31′ has a top surface 31a and a bottom surface 31b that is opposite to the top surface 31a in the vertical direction (as indicated by the direction of the dashed arrow in FIG. 4B). The semiconductor layer 31′, for example, is formed on the substrate 31 by an epitaxial growth process step, or, a part of the substrate 31 is used as the semiconductor layer 31′. The semiconductor layer 31′ can be formed by any method known to a person having ordinary skill in the art, so the details thereof are not redundantly explained here.

Still referring to FIG. 4B, next, the well 32 is formed in the semiconductor layer 31′. The well 32 is located below and in contact with the top surface 31a in the vertical direction. The well 32 has a first conductivity type. The well 32 can be formed by, for example but not limited to, an ion implantation process step which implants first conductivity type impurities in the semiconductor layer 31′ in the form of accelerated ions (as indicated by the downward dashed arrow in FIG. 4B), to form the well 32.

Next, please refer to FIG. 4C. The body region 36 is formed in the semiconductor layer 31′. The body region 36 is located below and in contact with the top surface 31a. The body region 36 is in contact with the well 32 in a channel direction (as indicated by the direction of the solid arrow in FIG. 4C). A part of the body region 36 is located vertically below and in contact with a gate 37 which will be formed later, to serve as an inversion current channel in an ON operation of the power device 300. The body region 36 has a second conductivity type. The body region 36 can be formed by, for example but not limited to, a lithography process step and an ion implantation process step, wherein the lithography process step forms a photo-resist layer 36′ as a mask and the ion implantation process step dopes second conductivity type impurities in the form of accelerated ions in the well 32 of the semiconductor layer 31′, to counter-dope the defined region in the well 32, so as to form the body region 36.

Next, please refer to FIG. 4D. A mask material 34′ is formed on the top surface 31a of the semiconductor layer 31′ via for example a deposition process step, so that the mask material 34′ cover the entire top surface 31a. In one embodiment, the mask material 34′ can be, for example but not limited to, silicon nitride (SiN) . Next, please refer to FIG. 4E. A photo-resist layer 38′ is formed on the mask material 34′ by a lithography process step. Next, please refer to FIG. 4F. A portion of the mask material 34′ which is not covered by the photo-resist layer 38′ is removed via an etching process step, so that the rest portion of the mask material 34′ which is not removed by the etching process step remains as a mask 34. The mask 34 is formed on and in contact with the upper surface 31a, to define the field oxide region 33 and the self-aligned drift region 35. Note that the mask 34 covers the top surface 31a of the entire low voltage region. Only the top surface 31a of the high voltage region is exposed, as shown in FIG. 4F.

Next, please refer to FIG. 4G. The self-aligned drift region 35 is formed in the semiconductor layer 31′, wherein the self-aligned drift region 35 is entirely located vertically below and in contact with the field oxide region 33. The self-aligned drift region 35 has the first conductivity type, wherein the self-aligned drift region 35 can be formed by, for example but not limited to, an ion implantation process step which implants first conductivity type impurities in the region defined by the mask 34 in the form of accelerated ions (as indicated by the downward dashed arrow in FIG. 4G), to form the self-aligned drift region 35. In one embodiment, the concentration of the first conductivity type impurities of the self-aligned drift region 35 is lower than the concentration of the first conductivity type impurities of the drain 39, and the concentration of the first conductivity type impurities of the self-aligned drift region 35 is higher than the concentration of the first conductivity type impurities of the well 32.

Next, please refer to FIG. 4H. Subsequent to the removal of the photo-resist layer 38′, an oxide layer 33′ is formed on the mask 34 via a deposition process step.

Next, please refer to FIG. 4I. A part of the oxide layer 33′ which does not belong to the region defined by the mask 34 is removed via the CMP process step, so as to form the field oxide region 33 on the top surface 31a. The field oxide region 33 is located between the gate 37 and the drain 39, both of which will be subsequently formed.

Next, please refer to FIG. 4J. The mask 34 is removed. Next, please refer to FIG. 4K. The gate 37 is formed on the top surface 31a of the semiconductor layer 31′. The field plate 37′ is formed on the field oxide region 33. Apart of the body region 36 is located vertically below and in contact with a gate 37, to serve as an inversion current channel in an ON operation of the power device 300. And, a part of the well 32 is located vertically below the gate 37, to serve as a drift current channel in an ON operation of the power device 300. The field plate 37′ is in contact with the field oxide region 33. The field plate 37′ is conductive and is electrically connected to a predetermined voltage level, so as to relieve an electric field distribution when the power device 300 is in operation. In one embodiment, the field plate 37′ is electrically connected to the source 38 which will be subsequently formed.

In this embodiment, the field plate 37′ can be formed by the same process step for forming the gate 37. In this embodiment, as shown in FIG. 4K, the field plate 37′ includes: a dielectric layer 371 in contact with the top surface 31a, a conductive layer 372 on the dielectric layer 371, and a spacer layer 273 which is electrically insulative. In another embodiment, the field plate 37′ can be a metal silicide layer formed by a metal silicidation process step or a metal layer formed by a metal formation process step (including deposition and patterning).

As shown in FIG. 4K, the gate 37 includes a dielectric layer 371 in contact with the top surface 31a, a conductive layer 372 on the dielectric layer 371, and a spacer layer 373 which is electrically insulative. The gate 37 turns ON and turns OFF the power device 300 according to a control signal.

Next, please refer to FIG. 4L. Each of the source 38 and the drain 39 is formed below and in contact with the top surface 31a. The source 38 and the drain 39 are located below and outside two sides of the gate 37 respectively. The side of the gate 37 which is closer to the source 38 is a source side and the side of the gate 37 which is closer to the drain 39 is a drain side, wherein the source 38 is located in the body region 36, and the drain 39 is located in the well 32 outside the drain side. A drift region 32a is formed in the well 32 between the drain 39 and the body region 36 in the channel direction, and is in contact with the top surface 31a, to separate the drain 39 from the body region 36 and to serve as a drift current channel in the ON operation of the power device 300. The source 38 and the drain 39 can be formed by, for example but not limited to, a lithography process step and an ion implantation process step, wherein the lithography process step forms a photo-resist layer and the ion implantation process step adopts the photo-resist layer together with the gate 37, the field plate 37′ and the field oxide region 33 as a mask and doping first conductivity type impurities in the body region 36 and the well 32 in the form of accelerated ions, to form the source 38 and the drain 39.

As described above, the present invention provides a power device having a field oxide region 33 and a self-aligned drift region 35, and a manufacturing method thereof. Advantages of the present invention include: that by covering the entire low voltage region and exposing only the top surface of the high voltage region, the present invention can protect the low voltage region; that, the present invention can prevent the isolation structure from being etched by a mask; that the present invention can form the self-aligned drift region and the field oxide region by one single mask; that the present invention can eliminate an undesirable effect on the low voltage region caused by a heating process step by replacing the heating process step with a CMP process step; and that the present invention can form the high voltage region which has an increasing impurities concentration distribution of the first conductivity type by the self-aligned drift region.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a metal silicide layer, may be added. For another example, the lithography process step is not limited to the mask technology but it can also include electron beam lithography, immersion lithography, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A power device, comprising:
a semiconductor layer, which is formed on a substrate, and has a top surface;
a well having a first conductivity type, which is formed in the semiconductor layer, wherein the well is located below and in contact with the top surface;
a body region having a second conductivity type, which is formed in the semiconductor layer, wherein the body region is located below and in contact with the top surface, and wherein the body region is in contact with the well in a channel direction;
a gate, which is formed on the top surface, wherein a part of the body region is located vertically below and in contact with the gate, to serve as an inversion current channel in an ON operation of the power device, and wherein a part of the well is located vertically below the gate, to serve as a drift current channel in the ON operation of the power device;
a source and a drain having the first conductivity type, which are formed below and in contact with the top surface, wherein the source and the drain are located below and outside two sides of the gate respectively, wherein the side of the gate which is closer to the source is a source side and the side of the gate which is closer to the drain is a drain side, and wherein the source is located in the body region, and the drain is located in the well outside the drain side;
a field oxide region, which is formed on the upper surface, wherein the field oxide region is located between the gate and the drain, and wherein the field oxide region is formed by steps including a chemical mechanical polish (CMP) process step; and
a self-aligned drift region having the first conductivity type, which is formed in the semiconductor layer, wherein the self-aligned drift region is entirely located vertically below and in contact with the field oxide region.

2. The power device of claim 1, further comprising:
a field plate which is conductive and which is formed on and in contact with the field oxide region, wherein the field plate is electrically connected to a predetermined voltage level, so as to relieve an electric field distribution when the power device is in operation.

3. The power device of claim 1, wherein a concentration of the first conductivity type impurities of the self-aligned drift region is lower than a concentration of the first conductivity type impurities of the drain, and wherein the concentration of the first conductivity type impurities of the self-aligned drift region is higher than a concentration of the first conductivity type impurities of the well.

4. The power device of claim 1, wherein the self-aligned drift region and the field oxide region are defined via a same lithography process step.

5. The power device of claim 2, wherein the field plate is electrically connected to the source.

6. A manufacturing method of the power device, comprising:
forming a semiconductor layer on a substrate, wherein the semiconductor layer has a top surface;
forming a well in the semiconductor layer, wherein the well has a first conductivity type, wherein the well is located below and in contact with the top surface;
forming a body region in the semiconductor layer, wherein the body region has a second conductivity type, wherein the body region is located below and in contact with the top surface, and wherein the body region is in contact with the well in a channel direction;
forming a gate on the top surface, wherein a part of the body region is located vertically below and in contact with the gate, to serve as an inversion current channel in an ON operation of the power device, and wherein a part of the well is located vertically below the gate, to serve as a drift current channel in the ON operation of the power device;
forming a source and a drain below and in contact with the top surface, wherein each of the source and the drain has the first conductivity type, wherein the source and the drain are located below and outside two sides of the gate respectively, wherein the side of the gate which is closer to the source is a source side and the side of the gate which is closer to the drain is a drain side, and wherein the source is located in the body region, and the drain is located in the well outside the drain side;
forming a field oxide region on the upper surface by steps including a chemical mechanical polish (CMP) process step, wherein the field oxide region is located between the gate and the drain; and
forming a self-aligned drift region in the semiconductor layer, wherein the self-aligned drift region has the first conductivity type, and wherein the self-aligned drift region is entirely located vertically below and in contact with the field oxide region.

7. The manufacturing method of claim 6, further comprising:
forming a mask on and in contact with the upper surface via a lithography process step, wherein the mask serves to define the field oxide region and the self-aligned drift region;
implanting first conductivity type impurities in the region defined by the mask in the form of accelerated ions by an ion implantation process step, to form the self-aligned drift region;
depositing an oxide layer via a deposition process step, and removing part of the oxide layer which does not belong to the region defined by the mask via the CMP process step; and
removing the mask.

8. The manufacturing method of claim 6, further comprising:
forming a field plate on and in contact with the field oxide region, wherein the field plate is conductive and is electrically connected to a predetermined voltage level, so as to relieve an electric field distribution when the power device is in operation.

9. The manufacturing method of claim 6, wherein a concentration of the first conductivity type impurities of the self-aligned drift region is lower than a concentration of the first conductivity type impurities of the drain, and wherein the concentration of the first conductivity type impurities of the self-aligned drift region is higher than a concentration of the first conductivity type impurities of the well.

10. The manufacturing method of claim 8, wherein the field plate is electrically connected to the source.
